(19) United States
(12) Patent Application Publication
(10) Pub. No.: US 2010/0238539 A1
(43) Pub. Date: Sep. 23, 2010

(54) OPTICAL SIGNAL AMPLIFYING APPARATUS

(75) Inventors: Yoshinobu Maeda, Yokkaichi-shi (JP); Masakazu Takagi, Higashiosaka-shi (JP)

Correspondence Address: OLIFF & BERRIDGE, PLC, P.O. BOX 320850, ALEXANDRIA, VA, 22320-4850, US

(73) Assignees: Optotriode Co., Ltd., Nagoya-shi (JP); Tatsuta Electric Wire & Cable Co., Ltd., Higashiosaka-shi (JP)

(21) Appl. No.: 12/733,068

(22) PCT Filed: Aug. 7, 2008
(86) PCT No.: PCT/JP2008/064214

§ 371 Date: May 17, 2010

(30) Foreign Application Priority Data
Aug. 10, 2007 (JP) 2007-209881

(51) Int. Cl. H01S 5/50

(52) U.S. Cl. 359/341.1

(57) ABSTRACT

An optical signal amplifying apparatus feeding back surrounding light to perform negative feedback optical amplification of a semiconductor optical amplifier is provided that enables a coupling structure to be simplified and miniaturized between the semiconductor optical amplifier and an optical fiber transmitting the output light from the semiconductor optical amplifier by using a fiber grating device. Since a first optical fiber grating device FGD1 is included on the output side of the first semiconductor optical amplifier 16 and, when a first input signal light L1 of a first wavelength λ1 is input to the first semiconductor optical amplifier 16, light Ls1 other than the first wavelength λ1 is reflected from the first optical fiber grating device FGD1 and directly input again to the first semiconductor optical amplifier 16, the coupling structure between the first semiconductor optical amplifier 16 and the first optical fiber grating device FGD1 transferring the output light Lₒᵤₜ from the first semiconductor optical amplifier 16 is simplified and miniaturized, which enables high-speed response.

### TECHNICAL FIELD

The present invention relates to an optical signal amplifying apparatus for amplifying an optical signal with lower distortion and a higher modulation degree and a three-terminal optical signal amplifying apparatus having an optical signal amplification effect.

### BACKGROUND ART

In a field of amplifying and transmitting an electric signal through conversion into an optical signal, it is known that the converted optical signal is more distorted as compared to the electric signal based on conversion characteristics of an electro-optical conversion element such as semiconductor laser and light-emitting diode. Especially, when a pulsed electric signal is input to semiconductor laser, the optical signal intensity abruptly increases at the rising edge of a pulse of an output optical signal and whisker-like overshooting optical signal waveforms are acquired. In general, if these optical signal waveforms are amplified by an optical amplifier, the distortion thereof is amplified and transmitted and a technique of optically reducing the distortion is not acquired. Although negative feedback amplification control is an important technique making up a low-distortion amplifier the electronics field, a corresponding technique is not acquired for the optical amplifier. Although a three-terminal amplification element having a signal amplification effect like a transistor exists in the electronics field, the element is not acquired in the optical electronics field.

In response, Maeda, one of the inventors, indicates that the cross-gain modulation phenomenon of a semiconductor optical amplifier (SOA) may be utilized for an input optical signal of a predetermined wavelength λ1 by feeding back surrounding light after passing through the semiconductor optical amplifier (light of wavebands centering on λ1 other than λ1) to the input side to amplify the input optical signal with lower distortion and calls the negative feedback optical amplification effect (Nonpatent Literature 1). Since the surrounding light exhibits the intensity inversion relative to the input optical signal due to XGM (cross-gain modulation) in this effect, the gain of the semiconductor optical amplifier is modulated in accordance with an input optical signal by feeding back the surrounding light to acquire the negative feedback optical amplification effect, to optically reduce the distortion of the signal waveform, and to acquire a higher modulation degree.

Nonpatent Literature 1: “Negative Feedback Optical Amplification Effect Based on Cross-Gain Modulation in Semiconductor Optical Amplifiers” (Applied Physics Letters, Volume 88, published 8 Mar. 2006)

### DISCLOSURE OF THE INVENTION

### Problems to be Solved by the Invention

Since an optical amplifying apparatus utilizing the conventional negative feedback optical amplification effect must input output light of a semiconductor optical amplifier to an end of an optical fiber to transmit the output light through the optical fiber in practice, an optical system is necessary for making the output light output from an end face of the semiconductor optical amplifier incident on a core at the center of an end face of the optical fiber. This optical system is made up of, for example, a first lens that converts the output light output from an active layer exposed on the end face of the semiconductor optical amplifier into parallel light; a second lens that condenses and makes the parallel light incident on the core at the center of the end face of the optical fiber; and an optical filter provided between the first lens and the second lens to transmit light of a first wavelength while reflecting the surrounding light thereof. Since a configuration retaining a plurality of optical components is necessary as above, the apparatus disadvantageously increases in size and becomes expensive. Although it is desirable to shorten a distance between the semiconductor optical amplifier and the optical filter reflecting light to the semiconductor optical amplifier as much as possible in consideration of response of the negative feedback optical amplification effect, the configuration elongates the optical path between the semiconductor optical amplifier and the optical filter and makes it difficult to acquire the sufficient negative feedback optical amplification effect.

In response, it is conceivable that a wavelength selectivity filter is fixedly provided by performing a film formation process for an end face of the semiconductor optical amplifier, the end face is a cleavage surface of a semiconductor substrate, is not stable in shape, and has different materials depending on positions, and it is difficult to form a wavelength selectivity filter, which is associated with accurate film formation control, due to influence of the edge effect. Since the light emitted from the semiconductor optical amplifier has a large divergence angle, if the wavelength selectivity filter is formed, it is unable to acquire the sufficient wavelength selection characteristic since the light is not parallel light. Since the wavelength selectivity filter has the wavelength selection characteristic varied depending on the incident angle, it is unable to acquire the constant wavelength selection characteristic for the light having a divergence angle.

The present invention was conceived in view of the situations and it is therefore the object of the present invention to provide an optical signal amplifying apparatus that modulates a gain of a semiconductor optical amplifier depending on an input optical signal by feeding back surrounding light to perform the negative feedback optical amplification and that enables a coupling structure to be simplified and miniaturized between the semiconductor optical amplifier and an optical fiber transmitting the output light from the semiconductor optical amplifier.

### Means for Solving the Problems

The aforementioned object is achieved according to the first mode of the invention, which provides an optical signal amplifying apparatus (a) having a first semiconductor optical amplifier that modulates light intensity amplification characteristics of light other than a first wavelength in accordance with an intensity of a first input signal light when the first input signal light of the first wavelength is input, the first semiconductor optical amplifier outputting the light acquired by amplifying the first input signal light and the light other than the first wavelength with the intensity inverted relative to the intensity of the first input signal light, the apparatus including: (b) a first optical fiber grating device on the output side of the first semiconductor optical amplifier, the first optical fiber grating device reflecting a whole or a portion of the light other than the first wavelength, (c) the light other than the first wavelength reflected by the first optical fiber grating device of the output light from the first semiconductor optical amplifier being input again to the first semiconductor optical amplifier.

The aforementioned object is achieved according to the second mode of the invention, which provides the optical signal amplifying apparatus of the first mode, wherein a first optical fiber grating portion of the first optical fiber grating device has reflection characteristics of transmitting the light of the first wavelength and reflecting the light of a whole or a portion of a band of wavelength shorter and/or longer than the first wavelength for amplified light having a bandwidth of at least 3 nm or more generated by amplification and is disposed close to the first semiconductor optical amplifier at a distance of an optical path length L.

The aforementioned object is achieved according to the third mode of the invention, which provides the optical signal amplifying apparatus of the second mode, wherein the optical path length L is L≦(c·t)/(20·n) where n denotes a refractive index of an optical transmission path between the first semiconductor optical amplifier and the first optical fiber grating portion; c (mm/sec) denotes the velocity of light in vacuum; and t (sec) denotes a time interval per one bit of the first input signal light.

The aforementioned object is achieved according to the fourth mode of the invention, which provides the optical signal amplifying apparatus of any one of the first to third modes, including (a) a second semiconductor optical amplifier that modulates light intensity amplification characteristics of light other than a second wavelength in accordance with an intensity of a second input signal light when the second input signal light of the second wavelength is input and that outputs the light acquired by amplifying the second input signal light and the light other than the second wavelength with the intensity inverted relative to the intensity of the second input signal light, and (b) a second optical fiber grating device that reflects a whole or a portion of the light other than the second wavelength of the light output from the second semiconductor optical amplifier, wherein (c) the second optical fiber grating device inputs the light other than the second wavelength and the first input signal light of the first wavelength to the first semiconductor optical amplifier.

The aforementioned object is achieved according to the fifth mode of the invention, which provides the optical signal amplifying apparatus of the fourth mode, wherein the second optical fiber grating device has (a) a second optical fiber grating portion provided on a fused extension portion formed by fusing and extending portions of two optical fibers, (b) a first input portion to which the output light of the second semiconductor optical amplifier is input, and (c) an output portion for the output to the first semiconductor optical amplifier (d) to reflect the light other than the second input signal light of the light input from the first input portion to the output portion different from the first input portion located on the same side as the first input portion relative to the fused extension portion and to transmit to the output portion the first input signal light input from a second input portion located on the opposite side of the first input portion relative to the fused extension portion.

The aforementioned object is achieved according to the sixth mode of the invention, which provides the optical signal amplifying apparatus of the fourth mode, wherein the second optical fiber grating device has (a) a second optical fiber grating portion provided on a first fused extension portion formed by fusing and extending portions of two optical fibers, (b) a first input portion to which the output light of the second semiconductor optical amplifier is input, and (c) an output portion for the output to the first semiconductor optical amplifier (d) to reflect the light other than the second input signal light of the light input from the first input portion to the output portion different from the first input portion located on the same side as the first input portion relative to the first fused extension portion and to transmit to the output portion the first input signal light input from a second input portion leading to a second fused extension potion disposed between the first fused extension potion and the output portion.

The aforementioned object is achieved according to the seventh mode of the invention, which provides the optical signal amplifying apparatus of any one of the first to third modes, including (a) a second semiconductor optical amplifier that modulates light intensity amplification characteristics of light other than a second wavelength in accordance with an intensity of a second input signal light when the second input signal light of the second wavelength is input and that outputs the light acquired by amplifying the second input signal light and the light other than the second wavelength with the intensity inverted relative to the intensity of the second input signal light, and (b) a third optical fiber grating device that reflects the amplified light of the second wavelength of the light output from the second semiconductor optical amplifier, wherein (c) the third optical fiber grating device inputs the light acquired by amplifying the second input signal light of the second wavelength and the first input signal light to the first semiconductor optical amplifier.

The aforementioned object is achieved according to the eighth mode of the invention, which provides the optical signal amplifying apparatus of the seventh mode, wherein the third optical fiber grating device has (a) a third optical fiber grating portion provided on a fused extension portion formed by fusing and extending portions of two optical fibers, (b) an input portion to which the output light of the second semiconductor optical amplifier is input, and (c) an output portion for the output to the first semiconductor optical amplifier (d) to reflect the amplified light of the second wavelength of the output light of the second semiconductor optical amplifier input from the input portion to the output portion different from the first input portion located on the same side as the first input portion relative to the fused extension portion and to transmit to the output portion the first input signal light input from a second input portion located on the opposite side of the first input portion relative to the fused extension portion.

The aforementioned object is achieved according to the ninth mode of the invention, which provides the optical signal amplifying apparatus of the seventh mode, wherein the third optical fiber grating device has (a) a third optical fiber grating portion formed on a first fused extension portion formed by fusing and extending portions of two optical fibers, (b) a first input portion to which the output light of the second semiconductor optical amplifier is input, and (c) an output portion for the output to the first semiconductor optical amplifier to (d) reflect the amplified light of the second wavelength of the output light of the second semiconductor optical amplifier input from the first input portion to the output portion different from the first input portion located on the same side as the first input portion relative to the fused extension portion and to transmit to the output portion the first input signal light input from a second input portion leading to a second fused extension portion located between the first fused extension portion and the output portion.

The aforementioned object is achieved according to the tenth mode of the invention, which provides the optical signal amplifying apparatus of any one of the first to ninth modes, wherein (a) the first optical fiber grating device has a hemispherically-ended lens on an end face, and wherein (b) the output light from the first semiconductor optical amplifier is directly made incident on the hemispherically-ended lens of the first optical fiber grating device.

The aforementioned object is achieved according to the eleventh mode of the invention, which provides the optical signal amplifying apparatus of any one of the fourth to sixth modes, wherein (a) the second optical fiber grating device has a hemispherically-ended lens on a fiber end face of the input portion and/or the output portion, wherein (b) the output light from the second semiconductor optical amplifier is directly output to the hemispherically-ended lens on the end face of the input portion of the second optical fiber grating device, and wherein the light from the output portion of the second optical fiber grating device is directly input to the first semiconductor optical amplifier.

The aforementioned object is achieved according to the twelfth mode of the invention, which provides the optical signal amplifying apparatus of any one of the seventh to ninth modes, wherein (a) the third optical fiber grating device has a hemispherically-ended lens on a fiber end face of the input portion and/or the output portion, wherein (b) the output light from the second semiconductor optical amplifier is directly output to the hemispherically-ended lens on the end face of the input portion of the third optical fiber grating device, and wherein the light from the output portion of the third optical fiber grating device is directly input to the first semiconductor optical amplifier.

The aforementioned object is achieved according to the thirteenth mode of the invention, which provides the optical signal amplifying apparatus of any one of the first to third modes, including (a) a second semiconductor optical amplifier that modulates light intensity amplification characteristics of light other than a second wavelength in accordance with an intensity of a second input signal light when the second input signal light of the second wavelength is input and that outputs the light acquired by amplifying the second input signal light and the light other than the second wavelength with the intensity inverted relative to the intensity of the second input signal light, and (b) an add/drop filter or an optical filter that reflects a whole or a portion of the light other than the second wavelength of the light output from the second semiconductor optical amplifier, wherein (c) the add/drop filter or the optical filter inputs the light other than the second wavelength and the first input signal light of the first wavelength to the first semiconductor optical amplifier.

The aforementioned object is achieved according to the fourteenth mode of the invention, which provides the optical signal amplifying apparatus of any one of the fourth to ninth and eleventh to thirteenth modes, wherein the first semiconductor optical amplifier and the second semiconductor optical amplifier are respectively provided on optical waveguides formed on one-chip semiconductor substrate.

The aforementioned object is achieved according to the fifteenth mode of the invention, which provides the optical signal amplifying apparatus of any one of the fourth to ninth and eleventh to thirteenth modes, wherein the second semiconductor optical amplifier is a reflective semiconductor optical amplifier including a reflecting means on one end.

The aforementioned object is achieved according to the sixteenth mode of the invention, which provides the optical signal amplifying apparatus of any one of the first to fifteenth modes, wherein the first semiconductor optical amplifier and/or the second semiconductor optical amplifier is a semiconductor optical amplifier including an active layer consisting of p-n junction and wherein the active layer is made up of bulk, quantum wells, strained superlattice, or quantum dots.

The aforementioned object is achieved according to the seventeenth mode of the invention, which provides the optical signal amplifying apparatus of any one of the fourth to ninth and eleventh to thirteenth modes, including a second input optical fiber that inputs the second input signal light of the second wavelength to the second semiconductor optical amplifier, wherein the second input optical fiber has an optical fiber grating portion that transmits the second input signal light of the second wavelength while reflecting surrounding light of the second wavelength to the second semiconductor optical amplifier.

The aforementioned object is achieved according to the eighteenth mode of the invention, which provides the optical signal amplifying apparatus of any one of the first to seventeenth modes, wherein the optical amplifying apparatus makes up a negative feedback optical amplifier, an optical limiter, an optical signal three-terminal amplifier, or an optical operational amplifier.

### Effects of the Invention

According to the first mode of the invention, the optical signal amplifying apparatus includes a first optical fiber grating device on the output side of the first semiconductor optical amplifier, the first optical fiber grating device reflecting a whole or a portion of the light other than the first wavelength, and the light other than the first wavelength reflected by the first optical fiber grating device of the output light from the first semiconductor optical amplifier is input again to the first semiconductor optical amplifier. Accordingly, the gain of the first semiconductor optical amplifier is modulated in accordance with an input optical signal by feeding back surrounding light exhibiting the intensity inversion to acquire the negative feedback optical amplification effect and to optically reduce distortion of a signal waveform, and a higher modulation degree is acquired. Since the first optical fiber grating device is disposed on the output side of the first semiconductor optical amplifier and the output light of the first wavelength from the first semiconductor optical amplifier is directly input to the first optical fiber grating device while light of other than the first wavelength is input again from the first optical fiber grating device to the first semiconductor optical amplifier, the coupling structure is simplified and miniaturized between the semiconductor optical amplifier and the first optical fiber grating device transmitting the output light from the semiconductor optical amplifier.

According to the second mode of the invention, a first optical fiber grating portion of the first optical fiber grating device has reflection characteristics of transmitting the light of the first wavelength and reflecting the light of a whole or a portion of a band of wavelength shorter and/or longer than the first wavelength for amplified light having a bandwidth of at least 3 nm or more generated by amplification and is disposed close to the first semiconductor optical amplifier at a distance of an optical path length L. Accordingly, the coupling structure is simplified and miniaturized between the semiconductor optical amplifier and the first optical fiber grating device transmitting the output light from the semiconductor optical amplifier.

According to the third mode of the invention, the optical path length L is L≦(c·t)/(20·n) where n denotes a refractive index of an optical transmission path between the first semiconductor optical amplifier and the first optical fiber grating portion; c (mm/sec) denotes the velocity of light in vacuum; and t (sec) denotes a time interval per one bit of the first input signal light. Accordingly, a higher response of the semiconductor optical amplifier is acquired. Therefore, since the surrounding light reflected by the first optical fiber grating device is immediately input again to the first semiconductor optical amplifier without delay, the distortion of the signal waveform is effectively reduced and a higher modulation degree is acquired.

According to the fourth mode of the invention, the optical signal amplifying apparatus includes (a) a second semiconductor optical amplifier that modulates light intensity amplification characteristics of light other than a second wavelength in accordance with an intensity of a second input signal light when the second input signal light of the second wavelength is input and that outputs the light acquired by amplifying the second input signal light and the light other than the second wavelength with the intensity inverted relative to the intensity of the second input signal light, and (b) a second optical fiber grating device that reflects a whole or a portion of the light other than the second wavelength of the light output from the second semiconductor optical amplifier, wherein (c) the second optical fiber grating device inputs the light other than the second wavelength and the first input signal light of the first wavelength to the first semiconductor optical amplifier. Accordingly, the small three-terminal optical signal amplifying apparatus is acquired that outputs the output light of the first wavelength modulated with the second input signal light of the second wavelength.

According to the fifth mode of the invention, the second optical fiber grating device has (a) a second optical fiber grating portion provided on a fused extension portion formed by fusing and extending portions of two optical fibers, (b) a first input portion to which the output light of the second semiconductor optical amplifier is input, and (c) an output portion for the output to the first semiconductor optical amplifier (d) to reflect the light other than the second input signal light of the light input from the first input portion to the output portion different from the first input portion located on the same side as the first input portion relative to the fused extension portion and to transmit to the output portion the first input signal light input from a second input portion located on the opposite side of the first input portion relative to the fused extension portion. Accordingly, the generally smaller three-terminal optical signal amplifying apparatus is acquired that outputs the output light of the first wavelength modulated with the second input signal light of the second wavelength.

According to the sixth mode of the invention, the second optical fiber grating device has (a) a second optical fiber grating portion provided on a first fused extension portion formed by fusing and extending portions of two optical fibers, (b) a first input portion to which the output light of the second semiconductor optical amplifier is input, and (c) an output portion for the output to the first semiconductor optical amplifier (d) to reflect the light other. than the second input signal light of the light input from the first input portion to the output portion different from the first input portion located on the same side as the first input portion relative to the first fused extension portion and to transmit to the output portion the first input signal light input from a second input portion leading to a second fused extension potion disposed between the first fused extension potion and the output portion. Accordingly, the generally smaller three-terminal optical signal amplifying apparatus is acquired that outputs the output light of the first wavelength modulated with the second input signal light of the second wavelength.

According to the seventh mode of the invention, the optical signal amplifying apparatus includes (a) a second semiconductor optical amplifier that modulates light intensity amplification characteristics of light other than a second wavelength in accordance with an intensity of a second input signal light when the second input signal light of the second wavelength is input and that outputs the light acquired by amplifying the second input signal light and the light other than the second wavelength with the intensity inverted relative to the intensity of the second input signal light, and (b) a third optical fiber grating device that reflects the amplified light of the second wavelength of the light output from the second semiconductor optical amplifier, wherein (c) the third optical fiber grating device inputs the light acquired by amplifying the second input signal light of the second wavelength and the first input signal light to the first semiconductor optical amplifier. Accordingly, the three-terminal optical signal amplifying apparatus is acquired.

According to the eighth mode of the invention, the third optical fiber grating device has (a) a third optical fiber grating portion provided on a fused extension portion formed by fusing and extending portions of two optical fibers, (b) an input portion to which the output light of the second semiconductor optical amplifier is input, and (c) an output portion for the output to the first semiconductor optical amplifier (d) to reflect the amplified light of the second wavelength of the output light of the second semiconductor optical amplifier input from the input portion to the output portion different from the first input portion located on the same side as the first input portion relative to the fused extension portion and to transmit to the output portion the first input signal light input from a second input portion located on the opposite side of the first input portion relative to the fused extension portion. Accordingly, the generally small three-terminal optical signal amplifying apparatus is acquired.

According to the ninth mode of the invention, the third optical fiber grating device has (a) a third optical fiber grating portion formed on a first fused extension portion formed by fusing and extending portions of two optical fibers, (b) a first input portion to which the output light of the second semiconductor optical amplifier is input, and (c) an output portion for the output to the first semiconductor optical amplifier to (d) reflect the amplified light of the second wavelength of the output light of the second semiconductor optical amplifier input from the first input portion to the output portion different from the first input portion located on the same side as the first input portion relative to the fused extension portion and to transmit to the output portion the first input signal light input from a second input portion leading to a second fused extension portion located between the first fused extension portion and the output portion. Accordingly, the generally small three-terminal optical signal amplifying apparatus is acquired.

According to the tenth mode of the invention, (a) the first optical fiber grating device has a hemispherically-ended lens on an end face, and (b) the output light from the first semiconductor optical amplifier is directly made incident on the hemispherically-ended lens of the first optical fiber grating device. Accordingly, an optical system is no longer necessary for coupling the first semiconductor optical amplifier and the first optical fiber grating device and the smaller optical amplifying apparatus is acquired.

According to the eleventh mode of the invention, (a) the second optical fiber grating device has a hemispherically-ended lens on a fiber end face of the input portion and/or the output portion, and (b) the output light from the second semiconductor optical amplifier is directly output to the hemispherically-ended lens on the end face of the input portion of the second optical fiber grating device, and wherein the light from the output portion of the second optical fiber grating device is directly input to the first semiconductor optical amplifier. Accordingly, an optical system is no longer necessary for coupling the second semiconductor optical amplifier and the second optical fiber grating device and coupling the first semiconductor optical amplifier and the second optical fiber grating device, and the smaller optical amplifying apparatus is acquired.

According to the twelfth mode of the invention, (a) the third optical fiber grating device has a hemispherically-ended lens on a fiber end face of the input portion and/or the output portion, and (b) the output light from the second semiconductor optical amplifier is directly output to the hemispherically-ended lens on the end face of the input portion of the third optical fiber grating device, and wherein the light from the output portion of the third optical fiber grating device is directly input to the first semiconductor optical amplifier. Accordingly, an optical system is no longer necessary for coupling the second semiconductor optical amplifier and the third optical fiber grating device and coupling the first semiconductor optical amplifier and the third optical fiber grating device, and the smaller optical amplifying apparatus is acquired.

According to the thirteenth mode of the invention, the optical signal amplifying apparatus includes (a) a second semiconductor optical amplifier that modulates light intensity amplification characteristics of light other than a second wavelength in accordance with an intensity of a second input signal light when the second input signal light of the second wavelength is input and that outputs the light acquired by amplifying the second input signal light and the light other than the second wavelength with the intensity inverted relative to the intensity of the second input signal light, and (b) an add/drop filter or an optical filter that reflects a whole or a portion of the light other than the second wavelength of the light output from the second semiconductor optical amplifier, wherein (c) the add/drop filter or the optical filter inputs the light other than the second wavelength and the first input signal light of the first wavelength to the first semiconductor optical amplifier. Accordingly, the generally small three-terminal optical signal amplifying apparatus is acquired.

According to the fourteenth mode of the invention, the first semiconductor optical amplifier and the second semiconductor optical amplifier are respectively provided on optical waveguides formed on one-chip semiconductor substrate. Accordingly, the optical signal amplifying apparatus is further miniaturized and is capable of being made into a single chip.

According to the fifteenth mode of the invention, the second semiconductor optical amplifier is a reflective semiconductor optical amplifier including a reflecting means on one end. Accordingly, a higher modulation degree is acquired.

According to the sixteenth mode of the invention, the first semiconductor optical amplifier and/or the second semiconductor optical amplifier is a semiconductor optical amplifier including an active layer consisting of p-n junction and wherein the active layer is made up of bulk, quantum wells, strained superlattice, or quantum dots. Accordingly, the optical signal amplifying apparatus is further miniaturized and is capable of being made into a single chip. Particularly, if the active layer is made up of the quantum wells or the quantum dots, the signal amplification is enabled in a higher frequency range on the order of 10 GHz and the high-speed switching performance is enhanced. If the active layer is made up of the strained superlattice, the optical signal amplifying apparatus with less wavelength dependency is acquired.

According to the seventeenth mode of the invention, the optical signal amplifying apparatus includes a second input optical fiber that inputs the second input signal light of the second wavelength to the second semiconductor optical amplifier, wherein the second input optical fiber has an optical fiber grating portion that transmits the second input signal light of the second wavelength while reflecting surrounding light of the second wavelength to the second semiconductor optical amplifier. Accordingly, the surrounding light of the first wavelength input to the first semiconductor optical amplifier is increased and, therefore, the modulation degree and the S/N ratio of the optical signal amplifying apparatus are further enhanced.

According to the eighteenth mode of the invention, the optical amplifying apparatus makes up a negative feedback optical amplifier, an optical limiter, an optical signal three-terminal amplifier, or an optical operational amplifier. Accordingly, a smaller negative feedback optical amplifier, optical limiter, optical signal three-terminal amplifier, or optical operational amplifier is acquired.

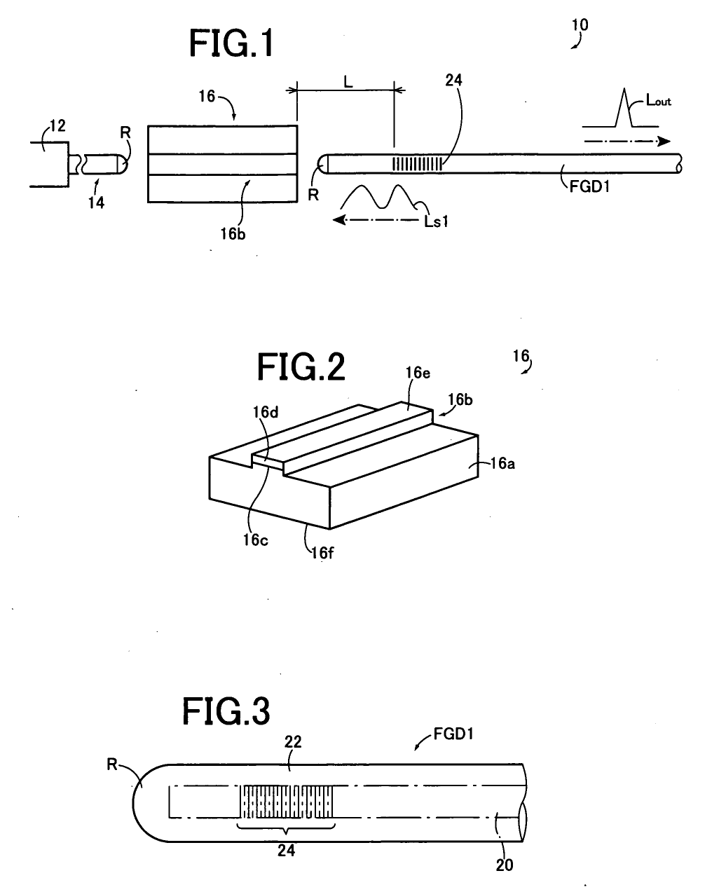

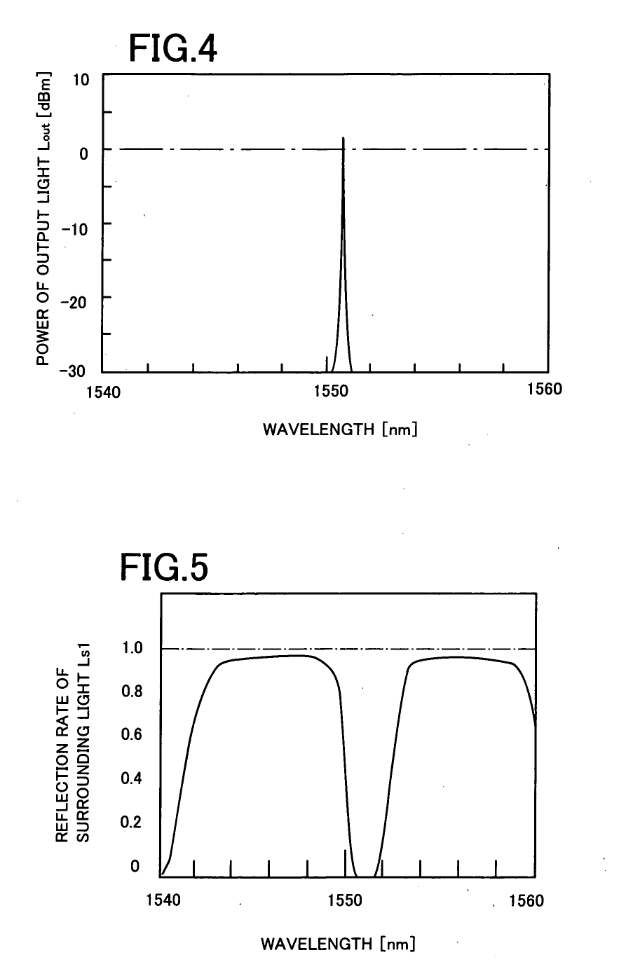

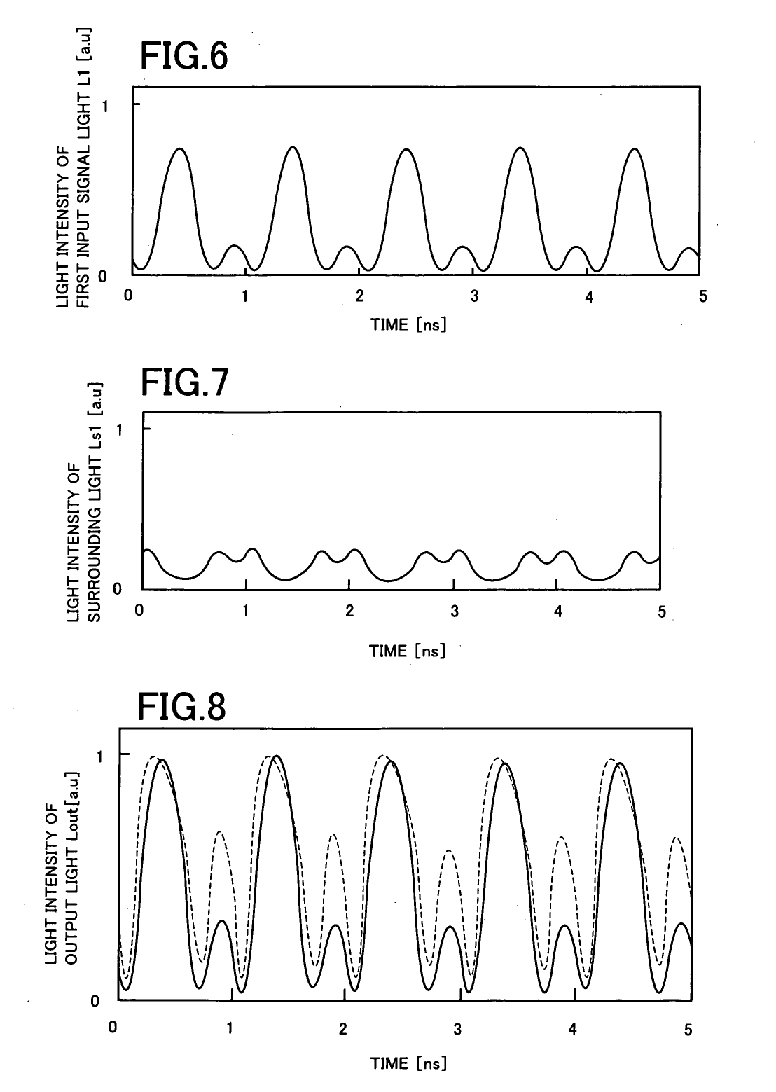

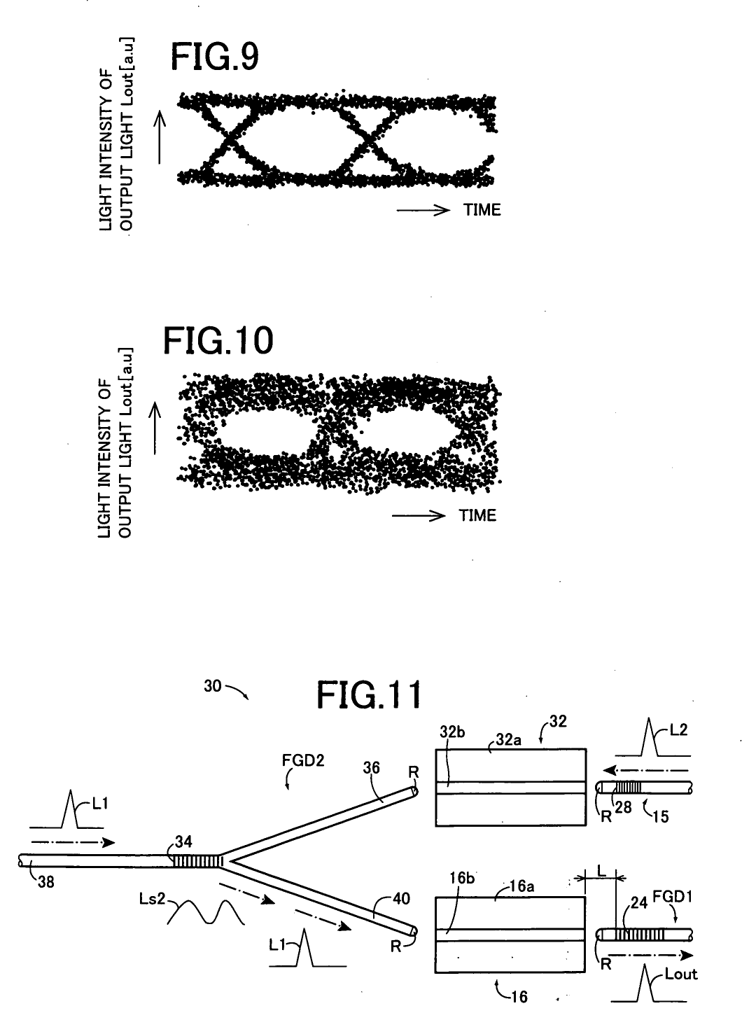

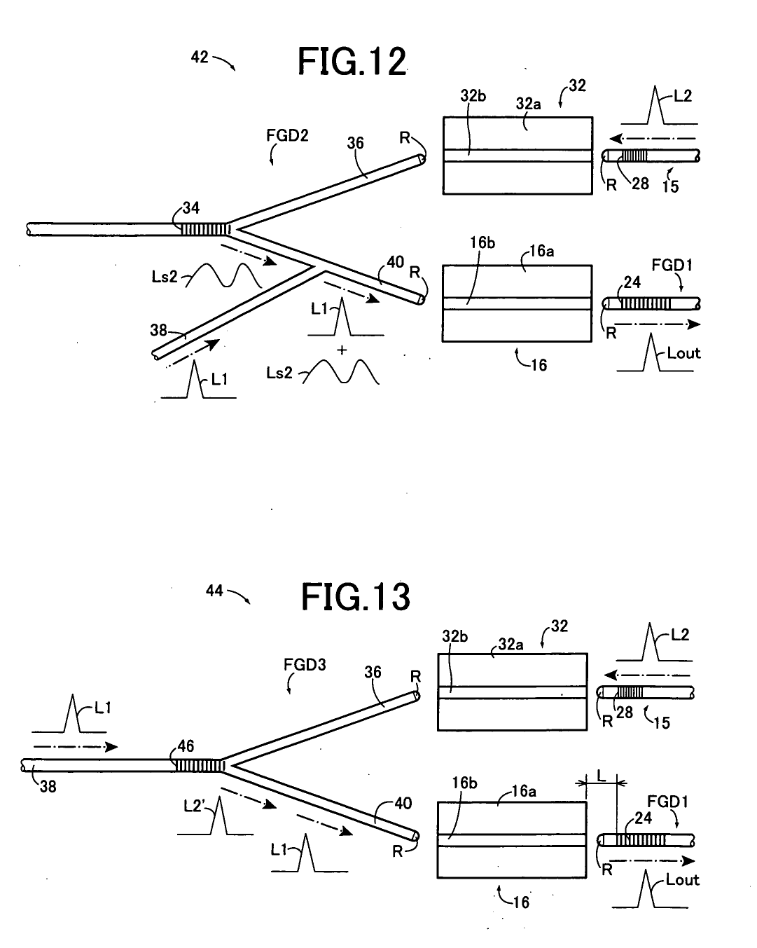

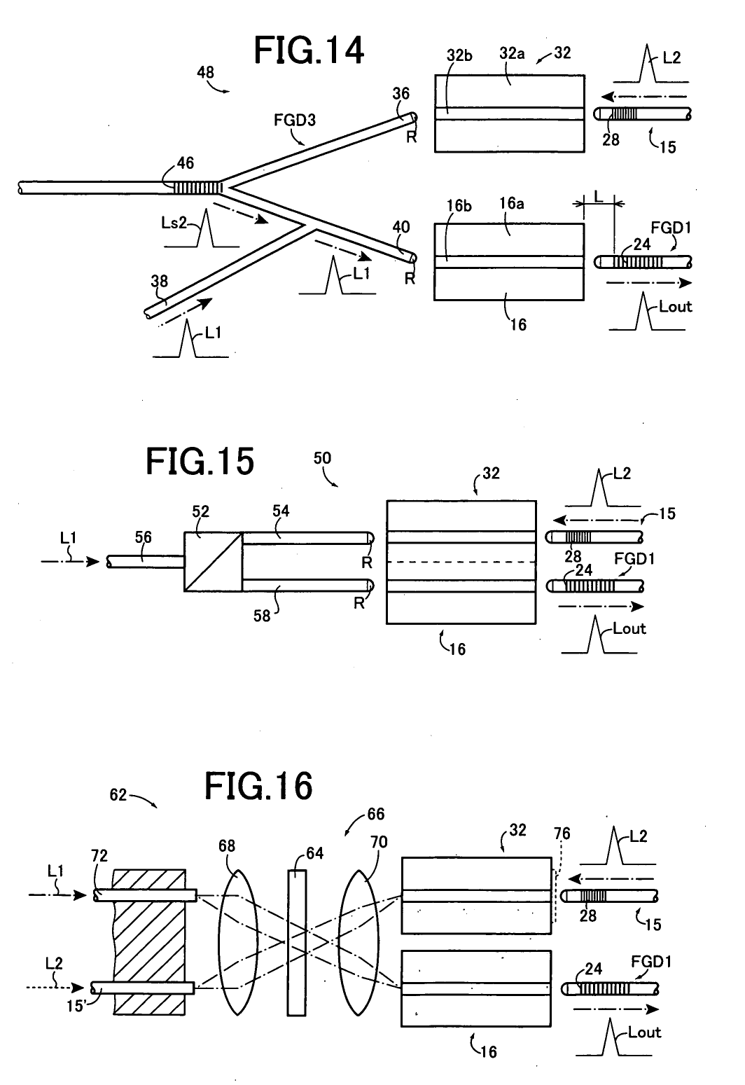

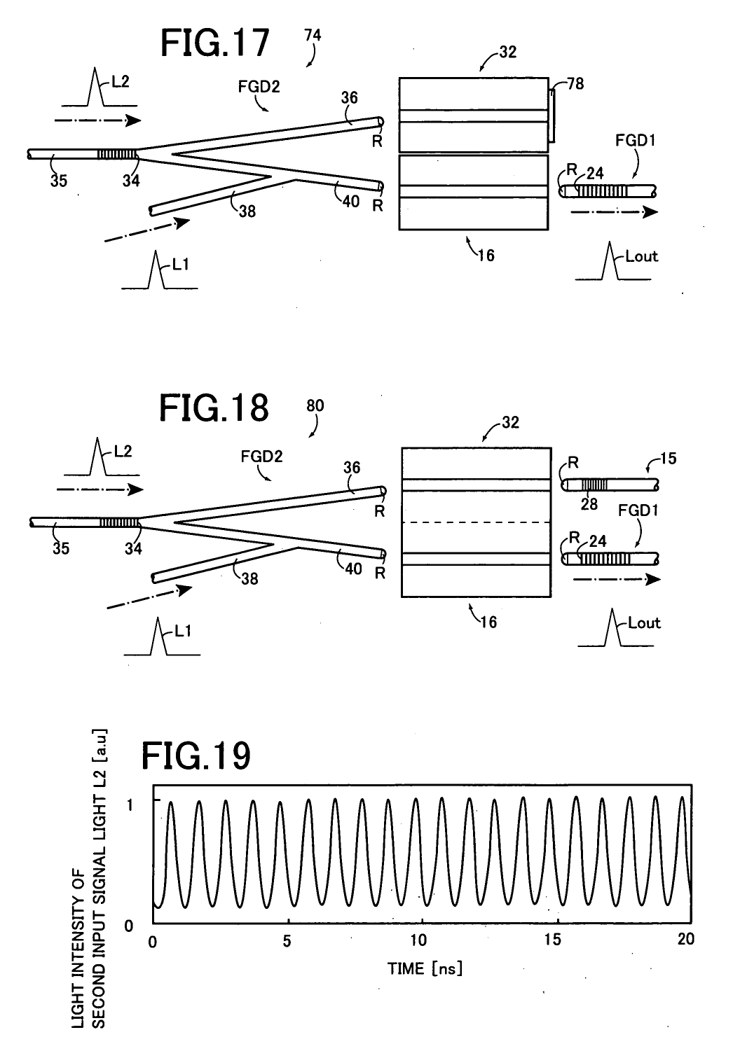

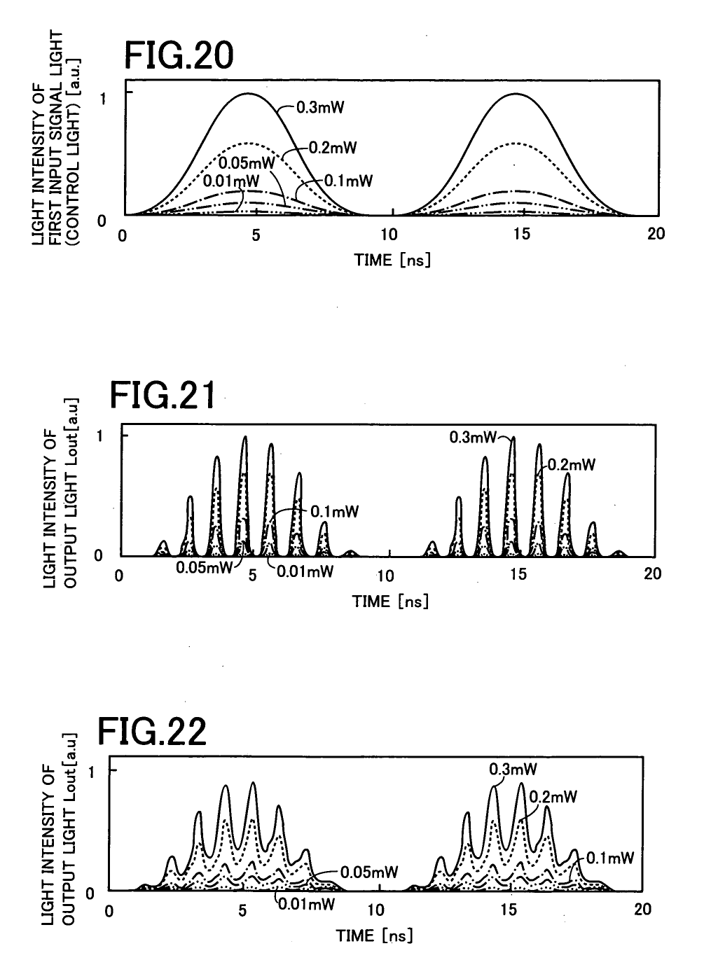

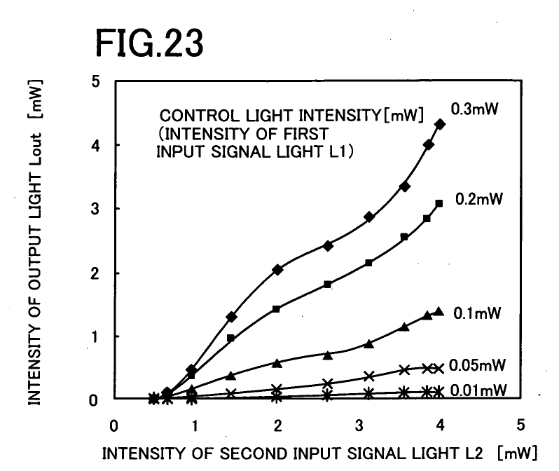

### BRIEF DESCRIPTION OF DRAWINGS

[FIG. 1] FIG. 1 is a schematic diagram for explaining a basic configuration of an optical signal amplifying apparatus of one embodiment of the present invention.

[FIG. 2] FIG. 2 is a perspective view for explaining a semiconductor chip making up a semiconductor optical amplifier of FIG. 1.

[FIG. 3] FIG. 3 is an enlarged cross-section diagram of a relevant part of an optical fiber grating device FGD1 of FIG. 1.

[FIG. 4] FIG. 4 is a spectrum diagram of transmission characteristics of an optical fiber grating portion provided on the optical fiber grating device FGD1 of FIG. 1.

[FIG. 5] FIG. 5 is a spectrum diagram of reflection characteristics of the optical fiber grating portion provided on the optical fiber grating device FGD1 of FIG. 1.

[FIG. 6] FIG. 6 is a diagram of intensity of a first input signal light L1 of the optical signal amplifying apparatus of FIG. 1.

[FIG. 7] FIG. 7 is a diagram of surrounding light reflected and input again to the optical fiber grating portion when the first input signal light L1 depicted in FIG. 6 is input in the optical signal amplifying apparatus of FIG. 1.

[FIG. 8] FIG. 8 is a diagram of output light (solid line) transmitted through the optical fiber grating portion when the first input signal light L1 depicted in FIG. 6 is input in the optical signal amplifying apparatus of FIG. 1, in comparison with output light (dashed line) when no negative feedback exists.

[FIG. 9] FIG. 9 is a diagram of measured values of an eye pattern of the optical signal amplifying apparatus of FIG. 1.

[FIG. 10] FIG. 10 is a diagram of measured values of an eye pattern when no negative feedback exists in the optical signal amplifying apparatus of FIG. 1.

[FIG. 11] FIG. 11 is a diagram for explaining a configuration of an optical signal amplifying apparatus of another embodiment (second embodiment) of the present invention.

[FIG. 12] FIG. 12 is a diagram for explaining a configuration of an optical signal amplifying apparatus of yet another embodiment (third embodiment) of the present invention, corresponding to FIG. 11.

[FIG. 13] FIG. 13 is a diagram for explaining a configuration of an optical signal amplifying apparatus of still another embodiment (fourth embodiment) of the present invention, corresponding to FIG. 11.

[FIG. 14] FIG. 14 is a diagram for explaining a configuration of an optical signal amplifying apparatus of yet still another embodiment (fifth embodiment) of the present invention, corresponding to FIG. 11.

[FIG. 15] FIG. 15 is a diagram for explaining a configuration of an optical signal amplifying apparatus of a further embodiment (sixth embodiment) of the present invention, corresponding to FIG. 11.

[FIG. 16] FIG. 16 is a diagram for explaining a configuration of an optical signal amplifying apparatus of a yet further embodiment (seventh embodiment) of the present invention, corresponding to FIG. 11.

[FIG. 17] FIG. 17 is a diagram for explaining a configuration of an optical signal amplifying apparatus of a still further embodiment (eighth embodiment) of the present invention, corresponding to FIG. 11.

[FIG. 18] FIG. 18 is a diagram for explaining a configuration of an optical signal amplifying apparatus of a yet still further embodiment (ninth embodiment) of the present invention, corresponding to FIG. 11.

[FIG. 19] FIG. 19 is a diagram of a waveform of a second input signal light L2 used for an experiment of the optical signal amplifying apparatus of FIG. 17.

[FIG. 20] FIG. 20 is a diagram of a waveform of the first input signal light L1 used for the experiment of the optical signal amplifying apparatus of FIG. 17 and functioning as control light.

[FIG. 21] FIG. 21 is a diagram of a waveform of output light acquired in the experiment of the optical signal amplifying apparatus of FIG. 17. [FIG. 22] FIG. 22 is a diagram of a waveform of output light when no negative feedback is performed in the experiment of the optical signal amplifying apparatus of FIG. 17. [FIG. 23] FIG. 23 is a diagram of three-terminal control characteristics acquired in the experiment of the optical signal amplifying apparatus of FIG. 17.

### EXPLANATIONS OF LETTERS OR NUMERALS

10, 30, 42, 44, 48, 50, 62, 74, 80: optical signal amplifying apparatus

14: first input optical fiber

15: second input optical fiber

16: first semiconductor optical amplifier

24: first optical fiber grating portion

32: second semiconductor optical amplifier

34: second optical fiber grating portion

35: third input portion

36: first input portion

38: second input portion

40: output portion

46: third optical fiber grating portion

52: add/drop filter

64: optical filter

76: reflecting film (reflecting means)

FGD1: first optical fiber grating device

FGD2: second optical fiber grating device

FGD3: third optical fiber grating device

L: optical path length

R: hemispherically-ended lens

### BEST MODES FOR CARRYING OUT THE INVENTION

An embodiment of the present invention will now be described with reference to the drawings. Dimension ratios, etc., of respective portions are not necessarily precisely depicted in the drawings used in the following description.

### First Embodiment

FIG. 1 is a diagram of a configuration of an optical signal amplifying apparatus 10 of one embodiment of the present invention. In FIG. 1, the optical signal amplifying apparatus 10 includes a first input optical fiber 14 that functions as an input means to guide a first input signal light L1 (laser beam) of a first wavelength λ1 output from a first signal light source 12; a first semiconductor optical amplifier 16 that modulates the light intensity amplification characteristics of light other than the first wavelength λ1, i.e., surrounding light (self-generated light) around the first wavelength λ1 in accordance with the intensity of the first input signal light L1 when the first input signal light L1 of the first wavelength λ1 is input from the optical fiber 14 and that outputs the light acquired by amplifying the first input signal light L1 and the light (surrounding light) other than the first wavelength with the intensity inverted relative to the intensity of the first input signal light L1; and a first optical fiber grating device FGD1 that is provided on the output side of the first semiconductor optical amplifier 16, that includes a first optical fiber grating portion 24 that transmits an amplified output light Lₒᵤₜ of the first wavelength λ1 of the output light while reflecting a light (surrounding light) Ls1 other than the first wavelength λ1 of the output light when the output light from the first semiconductor optical amplifier 16 is introduced, and that serves as an output optical fiber for inputting the reflected light again to the first semiconductor optical amplifier 16.

The first semiconductor optical amplifier 16 is made up of a chip-type element depicted in FIG. 2, for example, and includes a semiconductor substrate 16a made of compound semiconductor, for example, indium phosphide InP; an optical waveguide 16b made of the group III-V mixed crystal semiconductor epitaxially-grown thereon and consisting of a multilayer film having a relatively high refractive index formed with a predetermined width through photolithography; an active layer 16c that is p-n junction making up a portion of the multilayer film in the optical waveguide 16b and that is made up of one of bulk, multiple quantum wells, strained superlattice, and quantum dots; an upper electrode 16e fixedly mounted on the upper surface of the optical waveguide 16b; and a lower electrode 16f fixedly mounted on the lower surface of the semiconductor substrate 16a. While an injection current is applied between the upper electrode 16e and the lower electrode 16f, when the first input signal light L1 of the first wavelength λ1 is made incident and is transmitted through the active layer 16c in the course of propagation through the optical waveguide 16b, the light is subjected to the optical amplification due to induced radiation effect before output. Concurrently, due to so-called cross-gain modulation effect, surrounding light (self-generated light) is generated and also output that has a surrounding wavelength centering on the wavelength λ1 other than the wavelength λ1 and an intensity increased/reduced in inverse proportion to the intensity modulation of the first input signal light L1.

If the active layer 16c is made up of the multiple wells, for example, the layer is made up of six pairs of InGaAs and InGaP on the order of 100 nm lattice-matched by epitaxial growth from the semiconductor substrate 16a and guide layers (2000 Å) are sequentially provided that have a GRIN structure with compositions (refractive indexes) varied stepwise. The device length of the active layer 16c is on the order of 600 μm, for example.

The optical fiber 14 and the first optical fiber grating device FGD1 have respective hemispherically-ended lenses R functioning as convex lenses in the end faces on the first semiconductor optical amplifier 16 side such that the first input signal light L1 is directly input from the end face of the optical fiber 14 to the input-side end face 16d of the first semiconductor optical amplifier 16 and that the output light from the first semiconductor optical amplifier 16 is directly input to the end face of the first optical fiber grating device FGD1: Direct coupling is achieved between the end face of the optical fiber 14 and the input-side end face 16d of the first semiconductor optical amplifier 16 and between the output-side end face of the first semiconductor optical amplifier 16 and the end face of the first optical fiber grating device FGD1.

To immediately input again the surrounding light reflected from the first optical fiber grating portion 24 into the first semiconductor optical amplifier 16 to enhance the response performance thereof, a gap, i.e., an optical path length L between the output-side end face of the first semiconductor optical amplifier 16 and the end face of the first optical fiber grating portion 24 is set to satisfied L<(c·t)(20·n), where n denotes the refractive index of the transmission path therebetween; c (mm/sec) denotes the velocity of light in vacuum; and t (sec) denotes a time interval per one bit of the first input signal light L1. A predetermined alignment is implemented between the first semiconductor optical amplifier 16 and the end of the first optical fiber grating device FGD1 and the end of the optical fiber 14, which are then positionally-fixed by being supported on the bottom of a case or a wall not depicted.

The first optical fiber grating device FGD1 is an optical fiber made up of a substantially circular cylindrical shaped core 20 made of quartz SiO₂ with the addition of germanium Ge, for example, and a clad 22 made of quartz SiO₂ in a cylindrical shape covering the outer circumferential surface of the core 20, as depicted in FIG. 3, for example. The core 20 of the first optical fiber grating device FGD1 includes a first optical fiber grating portion 24 having periodical refractive-index variations typically on the order of 10000 to 20000 layers due to optically-induced refractive index variations by ultraviolet light irradiation formed into one or a plurality of groups in the propagation direction of the core 20 of the optical fiber by utilizing phase masks, etc. Although the refractive index variations have an equal period in some cases, the period may sequentially be changed in the chirp form. The first optical fiber grating portion 24 has characteristics of selectively reflecting the light of the wavelength corresponding to the reflective index period and the effective reflective index and functions as a wavelength selectivity filter that transmits the light of the first wavelength λ1 centering on 1551 nm, for example, while reflecting the light (surrounding light) having a bandwidth of at least 3 nm or more, for example, 6.5 nm different from the first wavelength λ1. FIG. 4 depicts the spectrum of the first input signal light L1 (output signal light) after amplification selectively transmitted through the first optical fiber grating portion 24 and FIG. 5 depicts the spectrum of the surrounding light selectively reflected by the first optical fiber grating portion 24.

Although FIG. 5 depicts the surrounding light including wavebands on the both sides of the first wavelength λ1, the waveband or a portion of the waveband on one side of the first wavelength λ1 may be reflected in the reflective characteristics of the first optical fiber grating portion 24, for example.

In accordance with experiments using the optical signal amplifying apparatus 10 configured as above by the inventors, etc., when the first input signal light L1 of the first wavelength λ1 depicted in FIG. 6 is input from the optical fiber 14 to the first semiconductor optical amplifier 16, the first input signal light L1 of the first wavelength λ1 is amplified and the intensity-inverted surrounding light other than the wavelength λ1 is generated in the first semiconductor optical amplifier 16 and the respective lights are multiplexed and output as output light. Although the output light is output to the first optical fiber grating device FGD1, the first optical fiber grating portion 24 included therein transmits the output light Lₒᵤₜ of the first wavelength λ1 of the output light while the surrounding light Ls1 of the first wavelength is reflected and input again to the first semiconductor optical amplifier 16. Since the re-input surrounding light Ls1 has the intensity inverted from the output light Lₒᵤₜ of the first wavelength λ1 by the cross-gain modulation, the gain (amplification rate) of the first semiconductor optical amplifier 16 is modulated for the first input signal light L1 of the first wavelength λ1. The re-input surrounding light acts as negative feedback light for the first input signal light L1. FIG. 7 depicts the reflective light of the first optical fiber grating portion 24 synchronously changed when the first input signal light L1 of the first wavelength λ1 depicted in FIG. 6 is input to the first semiconductor optical amplifier 16, i.e., the surrounding light Ls1 input again to the first semiconductor optical amplifier 16.

FIG. 8 depicts with a dashed line the output light Lₒᵤₜ output from the first optical fiber grating device FGD1 when the negative feedback light (surrounding light) Ls1 is not input to the first semiconductor optical amplifier 16 and depicts with a solid line the output light Lₒᵤₜ output from the first optical fiber grating device FGD1 when the negative feedback light (surrounding light) Ls1 is input in the experiments. As apparent from the comparison between the dashed line and the solid line, since the output light (signal light) Lₒᵤₜ output from the first optical fiber grating device FGD1 has no distortion in waveform and nonlinear distortion is reduced, it is apparent that the gain is stabilized and the nonlinear distortion is reduced because the negative feedback effect is acquired in the optical amplification by inputting the negative feedback light (surrounding light). Since the minimum value (baseline of signal) of the output light output from the first optical fiber grating device FGD1 is a value lower than that indicated by the dashed line, the modulation degree of the output signal light Lₒᵤₜ is enhanced and the SIN ratio is enhanced due to reduced noise because the negative feedback effect is acquired in the optical amplification by inputting the negative feedback light (surrounding light).

FIG. 9 depicts a result of eye-pattern measurement (a pattern displayed on an oscilloscope) of the output light Lₒᵤₜ output from the first optical fiber grating device FGD1 when the negative feedback light (surrounding light) Ls1 is input to the first semiconductor optical amplifier 16 in the experiment. A noise figure NF (ratio between the SN ratio of the input signal and the S/N ratio of the output signal) acquired in this case indicates 4 to 5 dB (decibels), which are preferable values equivalent to EDFA (erbium-doped fiber amplifier). FIG. 10 depicts a result of eye-pattern measurement (a pattern displayed on an oscilloscope) of the output light Lₒᵤₜ output from the first optical fiber grating device FGD1 when the negative feedback light (surrounding light) Ls1 is not input to the first semiconductor optical amplifier 16 in the experiment. In this case, a noise figure NF indicates 8 to 9 dB. For the eye-pattern measurement, the test pattern PEBS31, a mark rate of ½, and the standard mask SYM16/OC48 (2.48832 GHz) are used. As apparent from FIG. 9, if the negative feedback light (surrounding light) Ls1 is input to the first semiconductor optical amplifier 16, the signal of the output light Lₒᵤₜ output from the first optical fiber grating device FGD1 is much more stabilized.

In accordance with the optical signal amplifying apparatus 10 of the embodiment, since the first optical fiber grating device FGD1 reflecting a whole or a portion of the light other than first wavelength λ1 is included on the output side of the first semiconductor optical amplifier 16 and the surrounding light Ls1 other than the light Lₒᵤₜ of the first wavelength λ1 of the output light from the first semiconductor optical amplifier 16 is input again to the first semiconductor optical amplifier 16 as above, the gain of the first semiconductor optical amplifier 16 is modulated in accordance with the first input signal light L1 by feeding back the surrounding light Ls1 exhibiting the intensity inversion to acquire the negative feedback optical amplification effect and to effectively reduce the distortion of the signal waveform in the output light Lₒᵤₜ; and a higher modulation degree is acquired; and an error rate (bit error) is reduced by about two orders of magnitude. Since the first optical fiber grating device FGD1 is disposed on the output side of the first semiconductor optical amplifier 16 and the output light of the first wavelength λ1 from the first semiconductor optical amplifier 16 is directly input to the first optical fiber grating device FGD1 while the light Ls1 of other than the first wavelength λ1 is directly input again from the first optical fiber grating device FGD1 to the first semiconductor optical amplifier 16, the coupling structure is simplified and miniaturized between the first semiconductor optical amplifier 16 and the first optical fiber grating device FGD1 transmitting the output light Lₒᵤₜ from the first semiconductor optical amplifier 16.

In accordance with the optical signal amplifying apparatus 10 of the embodiment, since the first optical fiber grating device FGD1 has reflection characteristics of transmitting the output light Lₒᵤₜ of the first wavelength λ1 and reflecting the light Ls1 of a whole or a portion of the band of wavelength shorter and/or longer than the first wavelength λ1 for the amplified light having a bandwidth of at least 3 nm or more generated by amplification and is disposed close to the first semiconductor optical amplifier 16 at a distance of the optical path length L, the coupling structure is simplified and miniaturized between the first semiconductor optical amplifier 16 and the first optical fiber grating device FGD1 transmitting the output light Lₒᵤₜ from the first semiconductor optical amplifier 16.

In accordance with the optical signal amplifying apparatus 10 of the embodiment, since the optical path length L is L≦(c·t)/(20·n) where n denotes the refractive index of the optical transmission path between the first semiconductor optical amplifier 16 and the first optical fiber grating portion 24; c (mm/sec) denotes the velocity of light in vacuum; and t (sec) denotes a time interval per one bit of the first input signal light, a higher response of the first semiconductor optical amplifier 16 is acquired. Therefore, since the surrounding light Ls1 reflected by the first optical fiber grating device FGD1 is immediately input again to the first semiconductor optical amplifier 16 without delay, the distortion of the signal waveform is effectively reduced in the output light Lₒᵤₜ and a higher modulation degree is acquired.

In accordance with the optical signal amplifying apparatus 10 of the embodiment, since (a) the hemispherically-ended lens R is included in the end face of the first optical fiber grating device FGD1 and (b) the output light from the first semiconductor optical amplifier 16 is directly made incident on the hemispherically-ended lens R of the first optical fiber grating device FGD1, an optical system is no longer necessary for coupling the first semiconductor optical amplifier 16 and the first optical fiber grating device FGD1 and the smaller optical signal amplifying apparatus is acquired.

In accordance with the optical signal amplifying apparatus 10 of the embodiment, since the first semiconductor optical amplifier 16 is a semiconductor optical amplifier including the active layer 16c consisting of p-n junction and the active layer 16c is made up of the multiple quantum wells, the strained superlattice, of the quantum dots, the optical signal amplifying apparatus 10 is further miniaturized and is capable of being made into a single chip. Particularly, if the active layer is made up of the quantum wells or the quantum dots, the signal amplification is enabled in a higher frequency range on the order of 10 GHz and the high-speed switching performance is enhanced. If the active layer 16c is made up of the strained superlattice, the optical signal amplifying apparatus with less wavelength dependency is acquired.

In accordance with the optical signal amplifying apparatus 10 of the embodiment, since the first semiconductor optical amplifier 16 is provided one-by-one on the optical waveguide 16b formed on the one-chip semiconductor substrate 16a, the optical signal amplifying apparatus 10 is further miniaturized and is capable of being made into a single chip.

The optical signal amplifying apparatus 10 of the embodiment is able to make up a negative feedback optical amplifier, an optical limiter, an optical signal three-terminal amplifier, or an optical operational amplifier. In this way, a negative feedback optical amplifier, an optical limiter, an optical signal three-terminal amplifier, or an optical operational amplifier may be acquired that has a stable gain, reduced noise, and a higher modulation degree with smaller size.

### Second Embodiment

Another embodiment of the present invention will then be described. In the following description, portions common to the embodiments are denoted by the same reference numerals and will not be described.

An optical signal amplifying apparatus 30 of an embodiment depicted in FIG. 11 includes a second input optical fiber 15 that functions as a second input means to guide a second input signal light L2 of a second wavelength λ2 output from a second signal light source not depicted; a second semiconductor optical amplifier 32 that modulates the light intensity amplification characteristics of light other than the second wavelength λ2, i.e., surrounding light around the second wavelength λ2 in accordance with the intensity of the second input signal light L2 when the second input signal light L2 of the second wavelength λ2 is input from the optical fiber 15 and that outputs the light acquired by amplifying the second input signal light L2 and the light (surrounding light) Ls2 other than the second wavelength with the intensity inverted relative to the intensity of the second input signal light L2; a second optical fiber grating device FGD2 that receives the output light of the second semiconductor optical amplifier 32 to reflect and separate the light (surrounding light) Ls2 other than the second wavelength of the output light to multiplex and output the light with the first input signal light L1 of the first wavelength λ1; the first semiconductor optical amplifier 16 that modulates the first input signal light L1 with the surrounding light Ls2 of the second input signal light L2 by the cross-gain modulation when the multiplexed light of the light (surrounding light) Ls2 other than the second wavelength and the first input signal light L1 of the first wavelength λ1 is input from the second optical fiber grating device FGD2 and that outputs the amplified output signal light Lₒᵤₜ and the light (surrounding light) Ls1 other than the first wavelength with the intensity inverted relative to the intensity of the first input signal light L1; and the first optical fiber grating device FGD1 that includes the first optical fiber grating portion 24 that transmits the amplified output signal light Lₒᵤₜ of the first wavelength λ1 of the output light while reflecting the light (surrounding light) Ls1 other than the first wavelength λ1 of the output light when the output light from the first semiconductor optical amplifier 16 is introduced, and that serves as an output optical fiber for inputting the reflected light again to the first semiconductor optical amplifier 16.

The optical signal amplifying apparatus 30 of the embodiment is configured in the same way as compared to the optical signal amplifying apparatus 10 of the first embodiment except that the optical signal amplifying apparatus 30 further includes the second semiconductor optical amplifier 32 that modulates the light intensity amplification characteristics of the light other than the second wavelength λ2 in accordance with the intensity of the second input signal light L2 when the second input signal light L2 of the second wavelength λ2 is input from the second signal light source not depicted and that outputs the light acquired by amplifying the second input signal light L2 and the light Ls2 other than the second wavelength with the intensity inverted relative to the intensity of the second input signal light L2; and the second optical fiber grating device FGD2 that reflects a whole or a portion of the light Ls2 other than the second wavelength λ2 and that the second fiber grating device FGD2 inputs the light Ls2 other than the second wavelength λ2 and the first input signal light L1 of the first wavelength λ1 to the first semiconductor optical amplifier 16.

The second semiconductor optical amplifier 32 includes a semiconductor substrate 32a made of compound semiconductor, for example, indium phosphide (InP); an optical waveguide 32b made of the group III-V mixed crystal semiconductor epitaxially-grown thereon and consisting of a multilayer film having a relatively high refractive index formed with a predetermined width through photolithography; an active layer 32c that is p-n junction making up a portion of the multilayer film in the optical waveguide 32b and that is made up of one of bulk, multiple quantum wells, strained superlattice, and quantum dots; an upper electrode 32e fixedly mounted on the upper surface of the optical waveguide 32b; and a lower electrode 32f fixedly mounted on the lower surface of the semiconductor substrate 32a, as is the case with the first semiconductor optical amplifier 16 depicted in FIG. 2. The second wavelength λ2 and the first wavelength λ1 are wavelengths included in the waveband of each other's surrounding light or the second wavelength λ2 and the first wavelength λ1 are the same wavelengths.

The second fiber grating device FGD2 has a second optical fiber grating portion 34 provided on a fused extension portion formed by fusing and extending portions of two optical fibers; a first input portion 36 to which the output light of the second semiconductor optical amplifier 32 is input; a second input portion 38 to which the first input signal light L1 of the first wavelength λ1 output from the first signal light source 12 is input; and an output portion 40 for the output to the first semiconductor optical amplifier 16 to reflect the light Ls2 other than the second wavelength λ2 of the light input from the first input portion 36 to the output portion 40 different from the first input portion 36 located on the same side as the first input portion 36 relative to the second optical fiber grating portion 34 and to transmit to the output portion 40 the first input signal light L1 input from the second input portion 38 located on the opposite side of the first input portion 36 relative to the second optical fiber grating portion 34.

The end face of the optical fiber 15 includes a hemispherically-ended lens R functioning as a convex lens such that the second input signal light L2 of the second wavelength λ2 output from the end face of the optical fiber 15 is directly input to the end face of the second semiconductor optical amplifier 32. The end faces of the first input portion 36 and the output portion 40 of the second optical fiber grating device FGD2 also include respective hemispherically-ended lenses R functioning as convex lenses such that the output light of the second semiconductor optical amplifier 32 is directly input from the end face thereof to the first input portion 36 and that the light output from the output portion 40 is directly input to the input-side end face 16d of the first semiconductor optical amplifier 16. Direct coupling is achieved between the end face of the optical fiber 15 and the input-side end face of the second semiconductor optical amplifier 32, between the output-side end face of the second semiconductor optical amplifier 32 and the first input portion 36, and between the output portion 40 and the input-side end face of the first semiconductor optical amplifier 16.

The fused extension portion of the second fiber grating device FGD2 forms a so-called fiber coupler branching into a Y-shape by fusing and extending the respective cores 20 over a predetermined length and is configured to transmit the light of the second wavelength λ2 while the light Ls2 other than the second wavelength λ2 (surrounding light not including the second wavelength λ2) is reflected since the second fiber grating device FGD2 is provided with a second optical fiber grating portion 34 in the core 20 of the fused extension portion, which has periodical refractive-index variations typically on the order of 10000 to 20000 layers due to optically-induced refractive index variations by ultraviolet light irradiation formed into one or a plurality of groups in the propagation direction of the core 20 by utilizing phase masks, etc., as is the case with the first fiber grating device FGD1.

The optical signal amplifying apparatus 30 configured as above modulates the light intensity amplification characteristics of the surrounding light Ls2 that is the light other than the second wavelength λ2 in accordance with the intensity of the second input signal light L2 when the second input signal light L2 of the second wavelength λ2 is input from the optical fiber 15 to the second semiconductor optical amplifier 32 and inputs the light acquired by amplifying the second input signal light L2 and the surrounding light Ls2 other than the second wavelength with the intensity inverted relative to the intensity of the second input signal light L2 to the first input portion 36 of the second fiber grating device FGD2. The second fiber grating portion 34 of the second fiber grating device FGD2 transmits the light of the second wavelength λ2 while reflecting the surrounding light Ls2 toward the output portion 40, and the first input signal light L1 of the first wavelength λ1 made incident on the second input portion 38 is transmitted and transferred toward the output portion 40 and is multiplexed with the surrounding light Ls2 in the output portion 40. When the first input signal light L1 of the first wavelength λ1 and the surrounding light Ls2, i.e. the light other than the second wavelength λ2 are input from the output portion 40, the first semiconductor optical amplifier 16 outputs the output light Lₒᵤₜ of the first wavelength λ1 acquired by amplifying and modulating the first input signal light L1 of the first wavelength λ1 with the surrounding light Ls2 by the cross-gain modulation while outputting the surrounding light Ls1 other than the first wavelength λ1, which is self-generated light. The first fiber grating device FGD1 receives the output light of the first semiconductor optical amplifier 16 to transmit through the first optical fiber grating portion 24 and transfer the output light Lₒᵤₜ of the first wavelength λ1 included in the output light while reflecting and inputting the other surrounding light Ls1 other than the first wavelength λ1 again to the first semiconductor optical amplifier 16.

Although the output light Lₒᵤₜ of the embodiment is different from the first embodiment in that the output light Lₒᵤₜ is the signal acquired by not only simply amplifying but also modulating the first input signal light L1 of the first wavelength λ1 with the surrounding light Ls2 of the second input signal L2 of the second wavelength λ2, the output light Lₒᵤₜ of the embodiment is common with the first embodiment in that the output light of the first semiconductor optical amplifier 16 is received to transmit through the first optical fiber grating portion 24 and transfer the output light Lₒᵤₜ of the first wavelength λ1 included in the output light while the other surrounding light Ls1 other than the first wavelength λ1 is reflected and input again to the first semiconductor optical amplifier 16. Therefore, in accordance with the optical signal amplifying apparatus 30 of the embodiment, the same effect as the embodiment is acquired, and the small three-terminal optical signal amplifying apparatus is acquired that outputs the output light Lₒᵤₜ of the first wavelength λ1 modulated with the second input signal light L2 of the second wavelength λ2.

In this embodiment, the second input optical fiber 15 is provided with an optical fiber grating portion 28 that transmits the second input signal light L2 of the second wavelength λ2 while reflecting the surrounding light Ls2 that is light other than the second wavelength λ2 in the same way as the second fiber grating portion 34. Therefore, since the surrounding light Ls2 output to the input side of the second semiconductor optical amplifier 32 is reflected by the fiber grating portion 28 and output from the output side, the surrounding light Ls2 supplied to the first semiconductor optical amplifier 16 through the second fiber grating portion 34 from the second semiconductor optical amplifier 32 is augmented and, therefore, the modulation degree and the S/N ratio of the output light Lₒᵤₜ are more enhanced.

In accordance with the optical signal amplifying apparatus 30 of the embodiment, based on the same configuration as the first embodiment such that the first optical fiber grating device FGD1 reflecting a whole or a portion of the light other than the first wavelength λ1 is disposed on the output side of the first semiconductor optical amplifier 16 and that the surrounding light Ls1 other than the light Lₒᵤₜ of the first wavelength λ1 of the output light from the first semiconductor optical amplifier 16 is input again from the first optical fiber grating device FGD1 to the first semiconductor optical amplifier 16, each of the same operation effects as the embodiment is acquired.

In the optical signal amplifying apparatus 30 of the embodiment, the second optical fiber grating device FGD2 has (a) the second optical fiber grating portion 34 provided on the fused extension portion formed by fusing and extending portions of two optical fibers; (b) the first input portion 36 to which the output light of the second semiconductor optical amplifier 32 is input; (c) the output portion 40 for the output to the first semiconductor optical amplifier 16 to (d) reflect the surrounding light Ls2 that is the light other than the second wavelength λ2 of the light input from the first input portion 36 to the output portion 40 different from the first input portion 36 located on the same side as the first input portion 36 relative to the fused extension portion and to transmit to the output portion 40 the first input signal light L1 of the first wavelength λ1 input from the second input portion 38 located on the opposite side of the first input portion 36 relative to the fused extension portion, the generally smaller three-terminal optical signal amplifying apparatus is acquired that outputs the output light Lₒᵤₜ of the first wavelength modulated with the second input signal light L2 of the second wavelength λ2.

### Third Embodiment

An optical signal amplifying apparatus 42 of an embodiment depicted in FIG. 12 is configured in the same way as compared to the second optical fiber grating device FGD2 of the optical signal amplifying apparatus 30 of the second embodiment except that the position of the second input portion 38 is changed.

In FIG. 12, the second optical fiber grating device FGD2 has the second optical fiber grating portion 34 provided on a fused extension portion formed by fusing and extending portions of two optical fibers; the first input portion 36 to which the output light of the second semiconductor optical amplifier 32 is input; the second input portion 38 to which the first input signal light L1 of the first wavelength λ1 output from the first signal light source 12 is input; and the output portion 40 for the output to the first semiconductor optical amplifier 16 to reflect the light Ls2 other than the second wavelength λ2 of the light input from the first input portion 36 to the output portion 40 different from the first input portion 36 located on the same side as the first input portion 36 relative to the second optical fiber grating portion 34 and to transmit to the output portion 40 the first input signal light L1 input from the second input portion 38 branched between the second optical fiber grating portion 34 and the output portion 40 on the same side relative to the second optical fiber grating portion 34. At the branching point of the second input portion 38, a Y-shaped branching is made up by forming a second fused extension point of the core 20.

The second optical fiber grating device FGD2 of this embodiment has the same function as the second optical fiber grating device FGD2 of the second embodiment although a difference exists in that the second input portion 38 is branched between the second optical fiber grating portion 34 and the output portion 40. Therefore, the optical signal amplifying apparatus 42 of this embodiment has the same operation effects as the optical signal amplifying apparatus 30 of the second embodiment such as that the generally smaller three-terminal optical signal amplifying apparatus is acquired that outputs the output light Lₒᵤₜ of the first wavelength λ1 modulated with the second input signal light L2 of the second wavelength λ2.

### Fourth Embodiment

An optical signal amplifying apparatus 44 of an embodiment depicted in FIG. 13 is configured in the same way except that a third optical fiber grating device FGD3 is included instead of the second optical fiber grating device FGD2 of the optical signal amplifying apparatus 30 of the second embodiment.

Although the third optical fiber grating device FGD3 of this embodiment is common with the second optical fiber grating device FGD2 of the optical signal amplifying apparatus 30 in that the first input portion 36, the second input portion 38, and the output portion 40 are included, the third optical fiber grating device FGD3 of this embodiment is different in that a third optical fiber grating portion 46 disposed on a branching portion, i.e., a first fused extension portion reflects amplified light of the second signal light L2 of the second wavelength λ2 and transmits the surrounding light Ls2 not including the second wavelength λ2 in the opposite manner to the second optical fiber grating portion 34. In this embodiment, the first wavelength λ1 and the second wavelength λ2 are wavelengths different from each other.

When amplified light L2′ of the second input signal light L2 of the second wavelength λ2 and the first signal light L1 of the first wavelength λ1 are input from the output portion 40 of the third optical fiber grating device FGD3, the first semiconductor optical amplifying apparatus 16 of the optical signal amplifying apparatus 44 of an embodiment outputs the output light Lₒᵤₜ of the first wavelength λ1 acquired by amplifying and modulating the first input signal light L1 of the first wavelength λ1 with the amplified light L2′ of the second signal light L2 by the cross-gain modulation while outputting the surrounding light Ls1 other than the first wavelength λ1, which is self-generated light. The first fiber grating device FGD1 receives the output light of the first semiconductor optical amplifier 16 to transmit through the first optical fiber grating portion 24 and transfer the output light Lₒᵤₜ of the first wavelength λ1 included in the output light while reflecting and inputting the other surrounding light Ls1 other than the first wavelength λ1 again to the first semiconductor optical amplifier 16.

Although the output light Lₒᵤₜ of the embodiment is different from the second embodiment in that the output light Lₒᵤₜ is a signal acquired by modulating and amplifying the first input signal light L1 of the first wavelength λ1 with the second input signal L2 of the second wavelength λ2, the output light Lₒᵤₜ of the embodiment is common with the second embodiment in that the output light of the first semiconductor optical amplifier 16 is received to transmit through the first optical fiber grating portion 24 and transfer the output light Lₒᵤₜ of the first wavelength λ1 included in the output light while the other surrounding light Ls1 other than the first wavelength λ1 is reflected and input again to the first semiconductor optical amplifier 16. Therefore, in accordance with the optical signal amplifying apparatus 44 of the embodiment, the small three-terminal optical signal amplifying apparatus is acquired that outputs the output light Lₒᵤₜ of the first wavelength λ1 modulated with the second input signal light L2 of the second wavelength λ2.

In accordance with the optical signal amplifying apparatus 44 of the embodiment, based on the same configuration as the second embodiment such that the first optical fiber grating device FGD1 reflecting a whole or a portion of the light other than the first wavelength λ1 is disposed on the output side of the first semiconductor optical amplifier 16 and that the surrounding light Ls1 other than the light Lₒᵤₜ of the first wavelength λ1 of the output light from the first semiconductor optical amplifier 16 is input again from the first optical fiber grating device FGD1 to the first semiconductor optical amplifier 16, each of the same operation effects as the embodiment is acquired.

### Fifth Embodiment

An optical signal amplifying apparatus 48 of an embodiment depicted in FIG. 14 is configured in the same way as compared to the third optical fiber grating device FGD3 of the optical signal amplifying apparatus 44 of the fourth embodiment except that the position of the second input portion 38 is changed.

In FIG. 14, the third optical fiber grating device FGD3 has the third optical fiber grating portion 46 provided on a fused extension portion formed by fusing and extending portions of two optical fibers; the first input portion 36 to which the output light of the second semiconductor optical amplifier 32 is input; the second input portion 38 to which the first input signal light L1 of the first wavelength λ1 output from the first signal light source 12 is input; and the output portion 40 for the output to the first semiconductor optical amplifier 16 to reflect the amplified light of the second input signal light L2 of the second wavelength λ2 of the light input from the first input portion 36 to the output portion 40 different from the first input portion 36 located on the same side as the first input portion 36 relative to the third optical fiber grating portion 46 and to transmit to the output portion 40 the first input signal light L1 input from the second input portion 38 branched between the third optical fiber grating portion 46 and the output portion 40 on the same side relative to the third optical fiber grating portion 34. At the branching point of the second input portion 38, a Y-shaped branching is made up by forming a second fused extension point of the core 20.

The third optical fiber grating device FGD3 of this embodiment has the same function as the third optical fiber grating device FGD3 of the fourth embodiment although a difference exists in that the second input portion 38 is branched between the third optical fiber grating portion 46 and the output portion 40. Therefore, the optical signal amplifying apparatus 48 of this embodiment has the same operation effects as the optical signal amplifying apparatus 44 of the fourth embodiment such as that the generally smaller three-terminal optical signal amplifying apparatus is acquired that outputs the output light Lₒᵤₜ of the first wavelength λ1 modulated with the second input signal light L2 of the second wavelength λ2.

### Sixth Embodiment

An optical signal amplifying apparatus 50 of an embodiment depicted in FIG. 15 has the same function as the optical signal amplifying apparatuses 30 and 42 of the second and third embodiments except that an add/drop filter 52 is provided instead of the second optical fiber grating device FGD2, that the direct coupling is achieved between a first input optical fiber 54 provided on the add/drop filter 52 and the second semiconductor optical amplifier 32 and between an output optical fiber 58 provided on the add/drop filter 52 and the first semiconductor optical amplifier 16 through the hemispherically-ended lenses R functioning as convex lenses formed on the leading ends of the first input optical fiber 54 and the output optical fiber 58, and that the first semiconductor optical amplifier 16 and the second semiconductor optical amplifier 32 are made up of one common chip.

The add/drop filter 52 is provided with the first input optical fiber 54 to which the output light of the second semiconductor optical amplifier 32 is input; a second input optical fiber 56 to which the first input signal light L1 of the first wavelength λ1 output from the first signal light source 12 is input; and the output optical fiber 58 for the output to the first semiconductor optical amplifier 16. The add/drop filter 52 reflects the light Ls2 other than the second wavelength λ2 of the light input from the first input portion 36 to the output optical fiber 58 and transmits the first input signal light L1 input from the second input portion 38 to the output optical fiber 58. Therefore, in accordance with the optical signal amplifying apparatus 50 of this embodiment, the same operation effects as the optical signal amplifying apparatuses 30 and 42 of the second and third embodiments are acquired.

### Seventh Embodiment

An optical signal amplifying apparatus 62 of an embodiment depicted in FIG. 16 has the same function as the optical signal amplifying apparatuses 30 and 42 of the second and third embodiments except that an optical system 66 is provided that includes an optical filter (wavelength selectivity filter) 64 that transmits the first input signal light L1 of the first wavelength λ1 and the second input signal light L2 of the second wavelength λ2 while reflecting the surrounding light Ls2 other than the second wavelength λ2, instead of the second optical fiber grating device FGD2. It is desirable in this embodiment that the first wavelength λ1 of the first input signal light L1 and the second wavelength λ2 of the second input signal light L2 are the same or adjacent wavelengths.

The optical system 66 is made up of a pair of condensing lenses 68 and 70 with the optical filter 64 located therebetween and the coupling is optically achieved between a second input optical fiber 72 for outputting the first input signal light L1 of the first wavelength λ1 to the first semiconductor optical amplifier 16 and the first semiconductor optical amplifier 16 and between the second semiconductor optical amplifier 32 and the first semiconductor optical amplifier 16. Therefore, the surrounding light Ls2 other than the second wavelength λ2 of the light output from the second semiconductor optical amplifier 32 is reflected by the optical filter 64 and made incident on the first semiconductor optical amplifier 16 while the first input signal light L1 of the first wavelength λ1 is also made incident on the first semiconductor optical amplifier 16. Therefore, in accordance with the optical signal amplifying apparatus 62 of this embodiment, the same operation effects as the optical signal amplifying apparatuses 30 and 42 of the second and third embodiments are acquired.

A dash line of FIG. 16 depicts a variation. In this variation, a reflecting film 76 (reflecting means) is fixedly disposed on the input-side end face of the second semiconductor optical amplifier 32 and the second input signal light L2 of the second wavelength λ2 is input from an optical fiber 15′ disposed in parallel with the second input optical fiber 72. The second input signal light L2 of the second wavelength λ2 input from the optical fiber 15′ is transmitted through the optical filter 64 and is input to and amplified in the second semiconductor optical amplifier 32 and the surrounding light Ls2 other than the second wavelength λ2 is generated. As a result, the same operation effects as the embodiments are acquired. Since the second input signal light L2 of the second wavelength λ2 and the surrounding light Ls2 other than the second wavelength λ2 are augmented in the course of reflection and reciprocation by the reflecting film 76 in this variation, higher modulation degree and S/N ratio are acquired.

### Eighth Embodiment

Although an optical signal amplifying apparatus 74 of an embodiment depicted in FIG. 17 has the same function as the optical signal amplifying apparatus 42 of the third embodiment, differences exist in that the optical fiber 15 is removed to fixedly dispose a reflecting film 78 (reflecting means) on the input-side end face of the second semiconductor optical amplifier 32 and that the second optical fiber grating device FGD2 is used with four terminals. Since the reflecting film 78 is included, the second semiconductor optical amplifier 32 functions as a reflective semiconductor optical amplifier having characteristics such as a higher modulation degree.

The second fiber grating device FGD2 of this embodiment has the second optical fiber grating portion 34 provided on a fused extension portion formed by fusing and extending portions of two optical fibers; a third input portion 35 to which the second input signal light L2 of the second wavelength λ2 is input; the first input portion 36 to which the output light of the second semiconductor optical amplifier 32 is input; a second input portion 38 to which the first input signal light L1 of the first wavelength λ1 output from the first signal light source 12 is input; and an output portion 40 for the output to the first semiconductor optical amplifier 16.

When the second input signal light L2 of the second wavelength λ2 is input to the third input portion 35 of the second optical fiber grating device FGD2 in the optical signal amplifying apparatus 74, the second input signal light L2 is transmitted through the second optical fiber grating portion 34 and made incident on the second semiconductor optical amplifier 32. In the second semiconductor optical amplifier 32, the second input signal light L2 of the second wavelength λ2 is amplified while the surrounding light Ls2 not including the second wavelength λ2 is generated with the intensity phase inverted from the second input signal light L2 and, although the surrounding light Ls2 is output to the both sides, the surrounding light Ls2 going to the reflecting film 78 is reflected by the reflecting film 78 and made incident on the first input portion 36 of the second optical fiber grating device FGD2 together. The second fiber grating portion 34 reflects to the output portion 40 the surrounding light Ls2 other than the second wavelength λ2 of the light input from the first input portion 36 while the first input signal light L1 of the first wavelength λ1 acting as control light Lc is input from the second input portion 38, and the both lights are multiplexed. The surrounding light Ls2 other than the second wavelength λ2 and the first input signal light L1 of the first wavelength λ1 are multiplexed and input to the first semiconductor optical amplifier 16. Therefore, in accordance with the optical signal amplifying apparatus 74, the same operation effects as the optical signal amplifying apparatus 42 of the third embodiment are acquired and, since the second semiconductor optical amplifier 32 is a reflective semiconductor optical amplifier, further enhancements of the modulation degree and the S/N ratio are advantageously acquired.

### Ninth Embodiment

An optical signal amplifying apparatus 80 of an embodiment depicted in FIG. 18 is configured in the same way as compared to the optical signal amplifying apparatus 74 except that the input optical fiber 15 including, for example, the optical fiber grating portion 28 of FIG. 1 is provided instead of the reflecting film 78 fixedly attached to the end face of the second semiconductor optical amplifier 32 and that the first semiconductor optical amplifier 16 and the second semiconductor optical amplifier 32 are made up of one common chip. Although the surrounding light Ls2 generated within the second semiconductor optical amplifier 32 is output to the both sides, the surrounding light Ls2 going to the input optical fiber 15 is reflected by the optical fiber grating portion 28 and made incident on the first input portion 36 of the second optical fiber grating device FGD2 together and the same operation effect as the optical signal amplifying apparatus 74 depicted in FIG. 17 is acquired. Since the first semiconductor optical amplifier 16 and the second semiconductor optical amplifier 32 are made into a single chip in this embodiment, further miniaturization is advantageously achieved. In this embodiment, the input optical fiber 15 including the optical fiber grating portion 28 functions as a reflecting means for the surrounding light Ls2.

A result of an experiment conducted by the inventors, etc., with the optical signal amplifying apparatus 74 will then be described with reference to FIGS. 19 to 23. In this experiment, when the second input signal light L2 is input through the third input portion 35 and the first input portion 36 to the second semiconductor optical amplifier 32, the second input signal light L2 of the second wavelength λ2 is amplified while the surrounding light Ls2 other than the second wavelength λ2 is generated with the intensity inverted in the second semiconductor optical amplifier 32 to output the output light acquired by multiplexing the respective lights. Although the output light is output to the second optical fiber grating device FGD2, the second optical fiber grating portion 34 included therein transmits the amplified light Lₒᵤₜ of the second wavelength λ2 of the output light while the surrounding light Ls2 not including the second wavelength λ2 is reflected and input from the output portion 40 into the first semiconductor optical amplifier 16 along with the first input signal light L1 of the first wavelength λ1 input from the second input portion 38. FIG. 20 depicts the first input signal light L1 and the magnitude thereof is varied to control the magnitude of the output light Lₒᵤₜ.

In the first semiconductor optical amplifier 16, when the first input signal light L1 of the first wavelength λ1 and the surrounding light Ls2, i.e., the light other than the second wavelength λ2 are input from the output portion 40, the first input signal light L1 of the first wavelength λ1 is amplified and modulated by the cross-gain modulation with the surrounding light Ls2 to output the output light Lₒᵤₜ of the first wavelength λ1 while the surrounding light Ls1 other than the first wavelength λ1 is also output that is self-generated light. The first fiber grating device FGD1 receives the output light of the first semiconductor optical amplifier 16 and transmits and transfers the output light Lₒᵤₜ of the first wavelength λ1 included in the output light through the first optical fiber grating portion 24 while reflecting and inputting the other surrounding light Ls1 other than the first wavelength λ1 again to the first semiconductor optical amplifier 16. FIG. 21 depicts the output light Lₒᵤₜ of the first wavelength λ1 having the amplitude controlled by the first input signal light L1 acting as control light.

FIG. 22 depicts the output light Lₒᵤₜ of the first wavelength λ1 when the surrounding light Ls1 is not input again to the first semiconductor optical amplifier 16. As apparent from the comparison between a waveform depicted in FIG. 21 and a waveform depicted in FIG. 22, since the nonlinear distortion is reduced in the waveform depicted in FIG. 21, it is apparent that the gain is stabilized and the nonlinear distortion is reduced because the negative feedback effect is acquired in the optical amplification by inputting the negative feedback light (surrounding light). Since the waveform depicted in FIG. 21 has the minimum value (baseline of signal) lower than the waveform depicted in FIG. 22, the modulation degree of the output signal light Lₒᵤₜ is enhanced and the S/N ratio is enhanced due to reduced noise because the negative feedback effect is acquired in the optical amplification by inputting the negative feedback light (surrounding light).

FIG. 23 depicts characteristics among the second input signal light L2, the first input signal light L1 acting as control light, and the output light Lₒᵤₜ acquired from the experiment. It is apparent that the optical signal amplifying apparatus 74 uses only light and has three-terminal control characteristics like a transistor, i.e., functions as an optical three-terminal control apparatus.

Although the embodiments of the present invention have been described with reference to the drawings, the present invention is applicable to other aspects.

For example, although the second optical fiber grating device FGD2 or the third optical fiber grating device FGD3 is separately made up from the first semiconductor optical amplifier 16 and the second semiconductor optical amplifier 32 in the embodiments, the device may be made up within the waveguide to be integrally configured.

In the embodiments, portions other than the first semiconductor optical amplifier 16 and the first optical fiber grating device FGD1 may variously be modified. In fact, what are needed are the first semiconductor optical amplifier 16 and any portion transmitting the output light Lₒᵤₜ of the light output from the first semiconductor optical amplifier 16 and reflecting and inputting the surrounding light Ls1 again to the first semiconductor optical amplifier 16.

In the embodiments, the first semiconductor optical amplifier 16 and the first optical fiber grating portion 24 included in the first optical fiber grating device FGD1 desirably have larger light amount and intensity of the surrounding light Ls1 except the first wavelength λ1 reflected by the first optical fiber grating portion 2, use a bandwidth of desirably 5 nm or greater, more desirably 6.5 nm or greater, and preferably 5 nm on each side of the first wavelength λ1, i.e., a total of 10 nm although a certain effect may be acquired with a bandwidth of 3 nm, and are configured such that the reflection rate becomes 85% or greater, more preferably; 90% or greater. The first optical fiber grating portion 24 may reflect a whole or a portion of the band of wavelength shorter and/or longer than the first wavelength λ1 of the surrounding light Ls1 except the first wavelength λ1.

Although the first semiconductor optical amplifier 16 and the second semiconductor optical amplifier 32 are separately provided in the embodiments of FIGS. 11, 12, 13, 14, 16, and 17, the amplifiers may be made up of one common chip.

Although the second input optical fiber includes the optical fiber grating portion 28 in the embodiments of FIGS. 11, 12, 14, 15, 16, and 18, the optical fiber grating portion 28 may not necessarily be provided although the intensity of the surrounding light Ls2 made incident on the second semiconductor optical amplifier 32 is reduced by a certain degree.

Although not exemplary illustrated one by one, the present invention may variously be implemented in variously modified or altered aspects based on the knowledge of those skilled in the art.

1. An optical signal amplifying apparatus having a first semiconductor optical amplifier that modulates light intensity amplification characteristics of light other than a first wavelength in accordance with an intensity of a first input signal light when the first input signal light of the first wavelength is input, the first semiconductor optical amplifier outputting the light acquired by amplifying the first input signal light and the light other than the first wavelength with the intensity inverted relative to the intensity of the first input signal light, the apparatus comprising:
a first optical fiber grating device on the output side of the first semiconductor optical amplifier, the first optical fiber grating device reflecting a whole or a portion of the light other than the first wavelength,
the light other than the first wavelength reflected by the first optical fiber grating device of the output light from the first semiconductor optical amplifier being input again to the first semiconductor optical amplifier.

2. The optical signal amplifying apparatus of claim 1, wherein a first optical fiber grating portion of the first optical fiber grating device has reflection characteristics of transmitting the light of the first wavelength and reflecting the light of a whole or a portion of a band of wavelength shorter and/or longer than the first wavelength for amplified light having a bandwidth of at least 3 nm or more generated by amplification and is disposed close to the first semiconductor optical amplifier at a distance of an optical path length L.

3. The optical signal amplifying apparatus of claim 2, wherein the optical path length L is
L≦(c·t)/(20·n)
where n denotes a refractive index of an optical transmission path between the first semiconductor optical amplifier and the first optical fiber grating portion; c (mm/sec) denotes the velocity of light in vacuum; and t (sec) denotes a time interval per one bit of the first input signal light.

4. The optical signal amplifying apparatus of claim 1, including
a second semiconductor optical amplifier that modulates light intensity amplification characteristics of light other than a second wavelength in accordance with an intensity of a second input signal light when the second input signal light of the second wavelength is input and that outputs the light acquired by amplifying the second input signal light and the light other than the second wavelength with the intensity inverted relative to the intensity of the second input signal light, and
a second optical fiber grating device that reflects a whole or a portion of the light other than the second wavelength of the light output from the second semiconductor optical amplifier, wherein
the second optical fiber grating device inputs the light other than the second wavelength and the first input signal light of the first wavelength to the first semiconductor optical amplifier.

5. The optical signal amplifying apparatus of claim 4, wherein the second optical fiber grating device has a second optical fiber grating portion provided on a fused extension portion formed by fusing and extending portions of two optical fibers, a first input portion to which the output light of the second semiconductor optical amplifier is input, and an output portion for the output to the first semiconductor optical amplifier to reflect the light other than the second input signal light of the light input from the first input portion to the output portion different from the first input portion located on the same side as the first input portion relative to the fused extension portion and to transmit to the output portion the first input signal light input from a second input portion located on the opposite side of the first input portion relative to the fused extension portion.

6. The optical signal amplifying apparatus of claim 4, wherein the second optical fiber grating device has a second optical fiber grating portion provided on a first fused extension portion formed by fusing and extending portions of two optical fibers, a first input portion to which the output light of the second semiconductor optical amplifier is input, and an output portion for the output to the first semiconductor optical amplifier to reflect the light other than the second input signal light of the light input from the first input portion to the output portion different from the first input portion located on the same side as the first input portion relative to the first fused extension portion and to transmit to the output portion the first input signal light input from a second input portion leading to a second fused extension potion disposed between the first fused extension potion and the output portion.

7. The optical signal amplifyng apparatus of claim 1, including
a second semiconductor optical amplifier that modulates light intensity amplification characteristics of light other than a second wavelength in accordance with an intensity of a second input signal light when the second input signal light of the second wavelength is input and that outputs the light acquired by amplifying the second input signal light and the light other than the second wavelength with the intensity inverted relative to the intensity of the second input signal light, and
a third optical fiber grating device that reflects the amplified light of the second wavelength of the light output from the second semiconductor optical amplifier, wherein
the third optical fiber grating device inputs the light acquired by amplifying the second input signal light of the second wavelength and the first input signal light to the first semiconductor optical amplifier.

8. The optical signal amplifying apparatus of claim 7, wherein the third optical fiber grating device has a third optical fiber grating portion provided on a fused extension portion formed by fusing and extending portions of two optical fibers, an input portion to which the output light of the second semiconductor optical amplifier is input, and an output portion for the output to the first semiconductor optical amplifier to reflect the amplified light of the second wavelength of the output light of the second semiconductor optical amplifier input from the input portion to the output portion different from the first input portion located on the same side as the first input portion relative to the fused extension portion and to transmit to the output portion the first input signal light input from a second input portion located on the opposite side of the first input portion relative to the fused extension portion.

9. The optical signal amplifying apparatus of claim 7, wherein the third optical fiber grating device has a third optical fiber grating portion formed on a first fused extension portion formed by fusing and extending portions of two optical fibers, a first input portion to which the output light of the second semiconductor optical amplifier is input, and an output portion for the output to the first semiconductor optical amplifier to reflect the amplified light of the second wavelength of the output light of the second semiconductor optical amplifier input from the first input portion to the output portion different from the first input portion located on the same side as the first input portion relative to the fused extension portion and to transmit to the output portion the first input signal light input from a second input portion leading to a second fused extension portion located between the first fused extension portion and the output portion.

10. The optical signal amplifying apparatus of claim 1, wherein the first optical fiber grating device has a hemispherically-ended lens on an end face, and wherein
the output light from the first semiconductor optical amplifier is directly made incident on the hemispherically-ended lens of the first optical fiber grating device.

11. The optical signal amplifying apparatus of claim 4, wherein the second optical fiber grating device has a hemispherically-ended lens on a fiber end face of the input portion and/or the output portion, wherein
the output light from the second semiconductor optical amplifier is directly output to the hemispherically-ended lens on the end face of the input portion of the second optical fiber grating device, and wherein the light from the output portion of the second optical fiber grating device is directly input to the first semiconductor optical amplifier.

12. The optical signal amplifying apparatus of claim 7, wherein the third optical fiber grating device has a hemispherically-ended lens on a fiber end face of the input portion and/or the output portion, wherein
the output light from the second semiconductor optical amplifier is directly output to the hemispherically-ended lens on the end face of the input portion of the third optical fiber grating device, and wherein the light from the output portion of the third optical fiber grating device is directly input to the first semiconductor optical amplifier.

13. The optical signal amplifying apparatus of claim 1, including
a second semiconductor optical amplifier that modulates light intensity amplification characteristics of light other than a second wavelength in accordance with an intensity of a second input signal light when the second input signal light of the second wavelength is input and that outputs the light acquired by amplifying the second input signal light and the light other than the second wavelength with the intensity inverted relative to the intensity of the second input signal light, and
an add/drop filter or an optical filter that reflects a whole or a portion of the light other than the second wavelength of the light output from the second semiconductor optical amplifier, wherein
the add/drop filter or the optical filter inputs the light other than the second wavelength and the first input signal light of the first wavelength to the first semiconductor optical amplifier.

14. The optical signal amplifying apparatus of claim 4, wherein the first semiconductor optical amplifier and the second semiconductor optical amplifier are respectively provided on optical waveguides formed on one-chip semiconductor substrate.

15. The optical signal amplifying apparatus of claim 4, wherein the second semiconductor optical amplifier is a reflective semiconductor optical amplifier including a reflecting means on one end.

16. The optical signal amplifying apparatus of claim 1, wherein the first semiconductor optical amplifier and/or the second semiconductor optical amplifier is a semiconductor optical amplifier including an active layer consisting of p-n junction and wherein the active layer is made up of bulk, quantum wells, strained superlattice, or quantum dots.

17. The optical signal amplifying apparatus of claim 4, including a second input optical fiber that inputs the second input signal light of the second wavelength to the second semiconductor optical amplifier, wherein
the second input optical fiber has an optical fiber grating portion that transmits the second input signal light of the second wavelength while reflecting surrounding light of the second wavelength to the second semiconductor optical amplifier.

18. The optical signal amplifying apparatus of claim 1, wherein the optical amplifying apparatus makes up a negative feedback optical amplifier, an optical limiter, an optical signal three-terminal amplifier, or an optical operational amplifier.
